(19) United States
(12) Patent Application Publication
(10) Pub. No.: US 2011/0156049 A1
(43) Pub. Date: Jun. 30, 2011

(54) LED DEVICE AND FABRICATION METHOD THEREOF

(75) Inventor: CHIH-CHEN LAI, Tu-Cheng (TW)

(73) Assignee: HON HAI PRECISION INDUSTRY CO., LTD., Tu-Cheng (TW)

(21) Appl. No.: 12/873,215

(22) Filed: Aug. 31, 2010

(30) Foreign Application Priority Data
Dec. 24, 2009 (TW) 98144650

(51) Int. Cl. H01L 33/10; H01L 33/00; H01L 33/30

(52) U.S. Cl. 257/76; 257/98; 438/29; 438/46; 257/103; 257/E33.005; 257/E33.025

(57) ABSTRACT

A LED device includes a n-type first semiconductor layer, a p-type second semiconductor layer, an active layer between the first semiconductor layer and the second semiconductor layer, an electrode positioned on a surface of the second semiconductor layer away from the active layer, and an ohmic contacting layer positioned on a surface of the second semiconductor layer away from the active layer. The ohmic contacting layer includes a resistance region corresponding to the electrode and a conductive region surrounding the resistance region, in which the conductive region having less resistance than that of the resistance region.

### TECHNICAL FIELD

The present disclosure relates to a light emitting diode (LED) device and, particularly, to a GaN LED device.

### DESCRIPTION OF THE RELATED ART

A commonly used LED device includes an electrode, an ohmic contacting layer and a light emitting diode (including a first semiconductor layer, a second semiconductor layer and an active layer) between the electrode and the ohmic contacting layer. The ohmic contacting layer and the electrode are connected to a power supply during operation, but some light can be blocked by the electrode, thereby reducing luminance.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the views, and both the views are schematic.

FIG. 1 is a cross section of an embodiment of a LED device.

FIGS. 2 through 5 are cross sections of an LED device in each step of a fabrication method thereof as disclosed.

### DETAILED DESCRIPTION

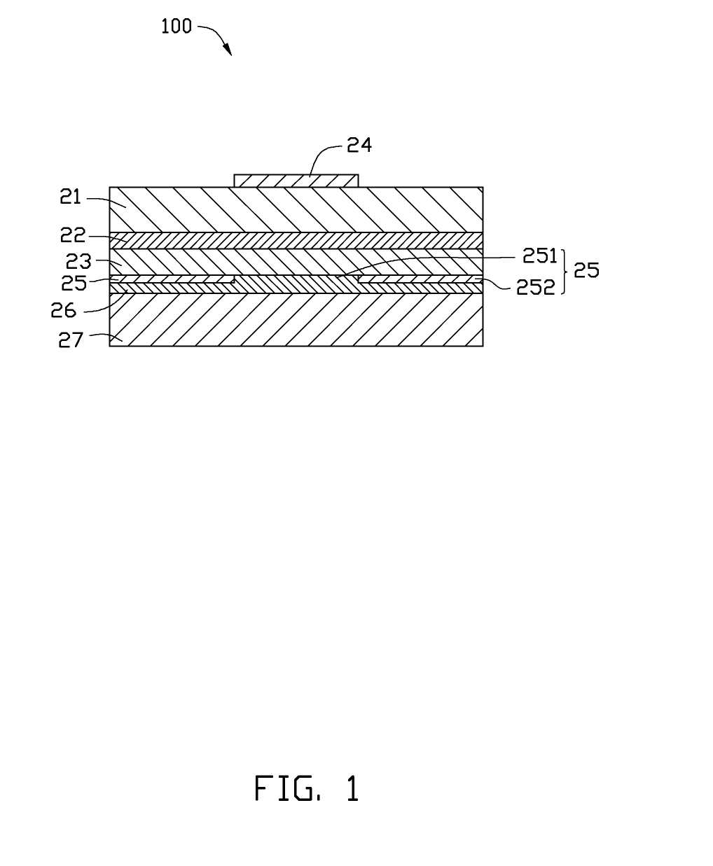

Referring to FIG. 1, an exemplary embodiment of an LED device 100 includes a n-type first semiconductor layer 21, an active layer 22, a p-type second semiconductor layer 23, an electrode 24, an ohmic contacting layer 25, a reflecting layer 26 and a substrate 27. The active layer 22 is disposed between the first semiconductor layer 21 and the second semiconductor layer 23. The ohmic contacting layer 25 is positioned on the second semiconductor layer 23, thus the second semiconductor layer 23 is between the active layer 22 and the ohmic contacting layer 25. The ohmic contacting layer 25 includes a resistance region 251 corresponding to the electrode 24 and a conducting region 252 surrounding the resistance region 251. The conducting region 252 and the resistance region 251 are of different materials, and a resistance of the resistance region 251 exceeds that of the conducting region 252. The reflecting layer 26 is fixed on a surface of the ohmic contacting layer 25 away from the first semiconductor layer 21. The electrode 24 is fixed on a surface of the second semiconductor layer 23 away from the active layer 22. During use, the electrode 24 connects to an outer power supply (not shown) by conductor (not shown). In the illustrated embodiment, the LED device 100 is a GaN LED device, the first semiconductor layer 21 is a n-type GaN layer; the second semiconductor layer 23 is a p-type GaN layer. The ohmic contacting layer 25 is nickel. The resistance region 251 is integrally formed with the reflecting layer 26. Alternatively, the ohmic contacting layer 25 may be gold or other conductive materials. Alternatively, the resistance region 251 may be formed individually with material different from that of the reflecting layer 26, and is fixed on the reflecting layer 26 by resin.

In use, the electrode 24 is connected to a positive electrode of the outer power supply, and the ohmic contacting layer 25 is connected to a negative electrode of the outer power supply, to supply electrical power to the LED device 100. About half of the light from the active layer 22 passes through the first semiconductor layer 21, and is emitted. The other half of the light from the active layer 22 is reflected by the reflecting layer 26, and passes through the first semiconductor layer 21, and is finally emitted. Since the resistance of the resistance region 251 exceeds that of the conducting region 252, thus a current is created between the electrode 24 and the conductive region 252, and a luminance ring is formed surrounding the electrode 24. The light blocked by the electrode 24 can be reduced, and a luminance of the LED device 100 is thereby improved.

A method of fabricating the LED device 100 follows:

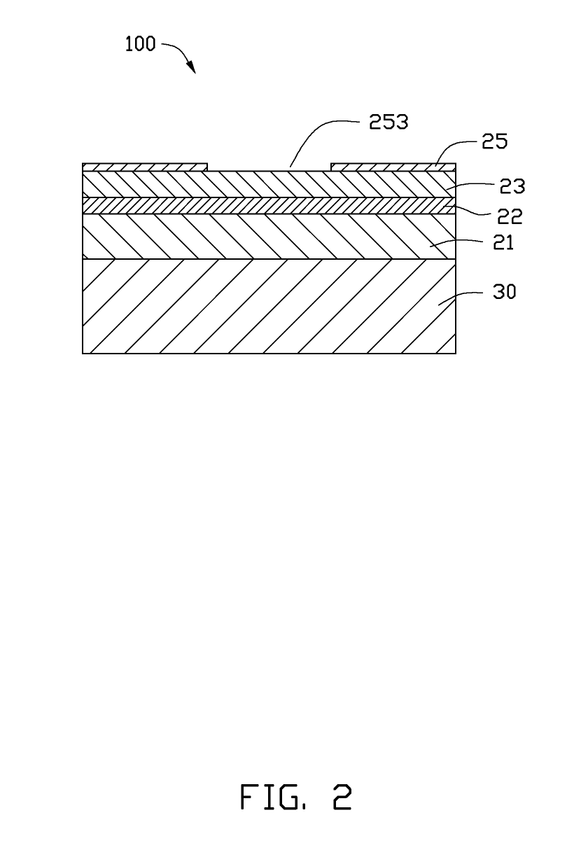

In a first step, referring to FIG. 2, the first semiconductor layer 21, the active layer 22 and the second semiconductor layer 23 are formed on a sapphire substrate 30 in that order. The ohmic contacting layer 25 is formed on the second semiconductor layer 23 by vapor deposition or sputtering deposition. The ohmic contacting layer 25 defines a through hole 253.

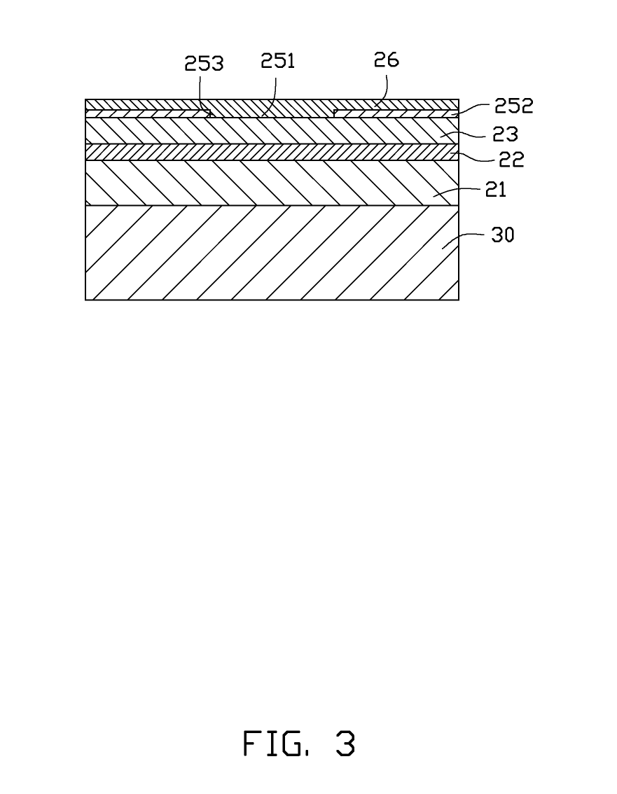

In a second step, referring to FIG. 3, the reflecting layer 26 is formed on the ohmic contacting layer 25 by electroplating or spraying, and the material of the reflecting layer 26 fills the through hole 253, to form the resistance region 251.

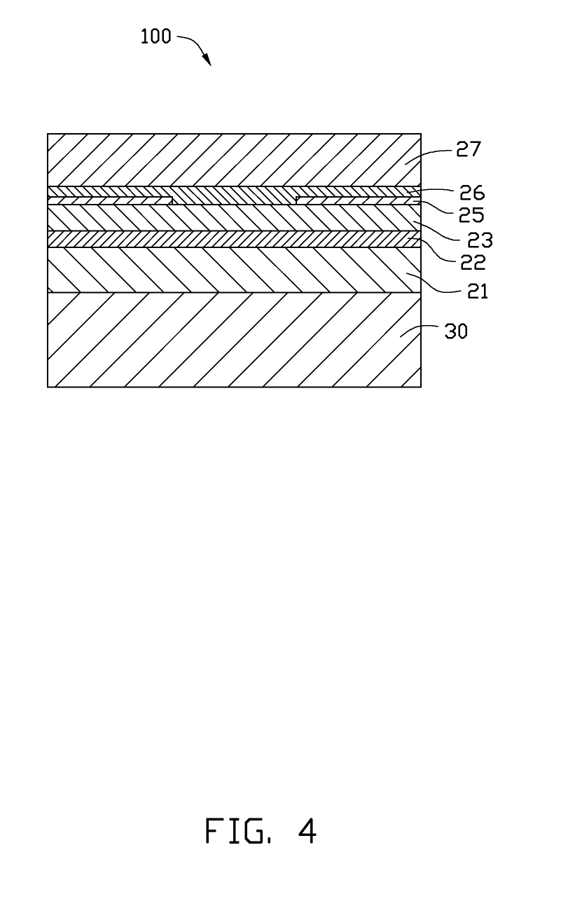

In a third step, referring to FIG. 4, the substrate 27 is formed on the reflecting layer 26.

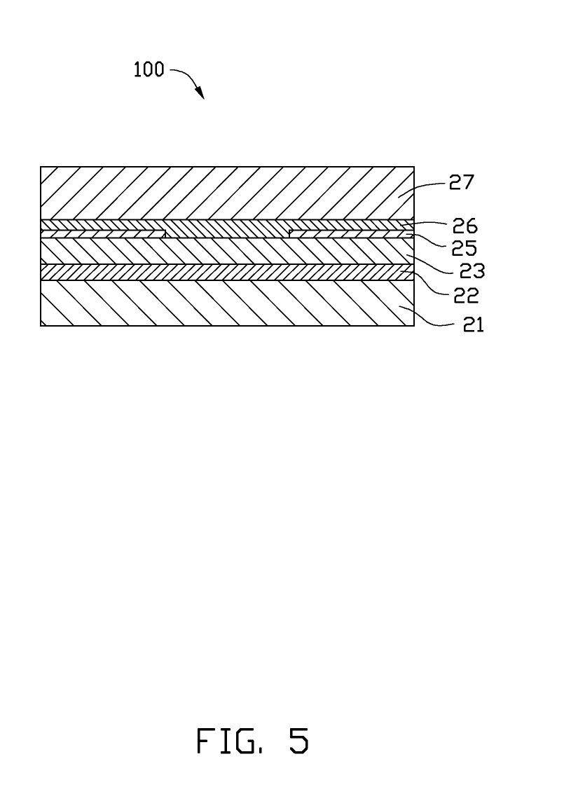

In a fourth step, referring to FIG. 5, the sapphire substrate 30 is removed by laser lift-off technology, in which the gallium nitride material is disintegrated by laser so that the sapphire substrate 30 is detached from the first semiconductor layer 21.

In a fifth step, the electrode 24 is formed and fixed on the first semiconductor layer 21 in a position corresponding to the resistance region 251, to form the LED device 100 (FIG. 1).

Finally, while particular embodiments have been described, the description is illustrative and is not to be construed as limiting. For example, various modifications can be made to the embodiments by those of ordinary skill in the art without departing from the true spirit and scope of the invention as defined by the appended claims.

What is claimed is:

1. A LED device comprising:
a n-type first semiconductor layer;
a p-type second semiconductor layer;
an active layer disposed between the first semiconductor layer and the second semiconductor layer;
an electrode positioned on a surface of the second semiconductor layer away from the active layer; and an ohmic contacting layer positioned on a surface of the second semiconductor layer away from the active layer, wherein the ohmic contacting layer comprises a resistance region corresponding to the electrode and a conductive region surrounding the resistance region, and the conducting region comprising less resistance than that of the resistance region.

2. The LED device of claim 1, wherein the first semiconductor layer and the second semiconductor layer are GaN.

3. The LED device of claim 1, wherein the ohmic contacting layer is nickel.

4. The LED device of claim 1, wherein the ohmic contacting layer is gold.

5. The LED device of claim 1, wherein the resistance region is integrally formed with the reflecting layer.

6. A method for fabricating a LED device, the method comprising:
providing a sapphire substrate, and forming a first semiconductor layer, an active layer and a second semiconductor layer on the sapphire substrate in that order, and then forming an ohmic contacting layer on the second semiconductor layer, the ohmic contacting layer comprising a conductive region, and defining a through hole in the conductive region;
forming a reflecting layer on the ohmic contacting layer, the material of the reflecting layer filling the through hole, thus forming a resistance region surrounded by the conductive region, and a resistance of the resistance region exceeding that of the conductive region;
forming a substrate on the reflecting layer;
removing the sapphire substrate; and
providing an electrode, and fixing the electrode on the first semiconductor layer corresponding to the resistance region.

7. The method for fabricating a LED device of claim 6, wherein the ohmic contacting layer is formed on the second semiconductor layer by vapor deposition.

8. The method for fabricating a LED device of claim 6, wherein the reflecting layer is formed on the ohmic contacting layer by electroplating.

9. The method for fabricating a LED device of claim 8, wherein the sapphire substrate is removed by laser lift-off technology.
